(19) United States
(12) Patent Application Publication
(10) Pub. No.: US 2026/0334264 A1
(43) Pub. Date: Oct. 22, 2026

(54) SEMICONDUCTOR APPARATUS AND MANUFACTURING METHOD

(71) Applicant: FUJI ELECTRIC CO., LTD., Kanagawa (JP)

(72) Inventors: Kohei YAMAUCHI, Hachioji-City (JP); Eiji MOCHIZUKI, Matsumoto-city (JP)

(21) Appl. No.: 19/565,397

(22) Filed: Mar. 12, 2026

(30) Foreign Application Priority Data
Apr. 22, 2025 (JP) 2025-070874

(51) Int. Cl. H10W 70/65; H10W 70/05; H10W 70/63; H10W 70/68; H10W 70/685

(52) U.S. Cl. CPC H10W 70/658; H10W 70/05; H10W 70/63; H10W 70/682; H10W 70/685

(57) ABSTRACT

Provided is a semiconductor apparatus comprising: a wiring substrate on which circuit wiring is provided; and a semiconductor device embedded in the wiring substrate and connected to the circuit wiring, wherein the semiconductor device has an upper surface, and a first main electrode plate and a control electrode plate provided on the upper surface, and wherein the wiring substrate has one or more units of via wiring in contact with the control electrode plate or the first main electrode plate. The via wiring may extend 20 μm or more inside the control electrode plate or the first main electrode plate.

The contents of the following patent application(s) are incorporated herein by reference:
NO. 2025-070874 filed in JP on Apr. 22, 2025.

### BACKGROUND

### 1. Technical Field

The present invention relates to a semiconductor apparatus and a manufacturing method.

### 2. Related Art

Patent Document 1 describes a substrate with built-in power components comprising “a power semiconductor element embedded in an insulating layer”, “wherein wiring is connected to an electrode terminal of the power semiconductor element via a via” (claim 1). Patent Document 2 describes a semiconductor device comprising “a mounting substrate having, on the mounting surface for the switching element, first main electrode wiring connected to the first main electrode and control wiring connected to the control electrode, wherein, in a region of the mounting surface for the switching element where the switching element is not arranged, the mounting substrate has a first main electrode plate connected to the first main electrode wiring and a control electrode plate connected to the control electrode (claim 1).

### RELATED ART DOCUMENTS

### Patent Documents

Patent Document 1: Japanese Patent Application Publication No. 2022-95471
Patent Document 2: International Publication No. 2024/143541

### BRIEF DESCRIPTION OF THE DRAWINGS

FIG. 1 is a perspective view of a switching element 10 according to the present embodiment.

FIG. 2 is a perspective view of a semiconductor device 200 according to the present embodiment.

FIG. 3 illustrates a manufacturing method of the semiconductor device 200 according to the present embodiment.

FIG. 4 is a perspective view of a configuration in which a second main electrode plate 230 is bonded to the switching element 10 according to the present embodiment.

FIG. 5 is a perspective view of a mounting substrate 210 according to the present embodiment.

FIG. 6 is a perspective view of a configuration in which a switching element 10, to which the second main electrode plate 230 is bonded, is bonded to the mounting substrate 210 according to the present embodiment.

FIG. 7 is a perspective view of a configuration in which a first main electrode plate 220, a control electrode plate 240, and a sub-electrode plate 250 are bonded to the mounting substrate 210 according to the present embodiment.

FIG. 8 is a cross-sectional view illustrating an example of a semiconductor apparatus 600 according to one embodiment of the present invention.

FIG. 9 is a cross-sectional view illustrating an example of the semiconductor device 200.

FIG. 10 is a diagram illustrating an example of an enlarged view of via wiring 631.

FIG. 11 is a diagram illustrating an example of the via wiring 631 provided on each electrode plate.

FIG. 12 is a diagram illustrating an arrangement example of each electrode plate on the upper surface of the semiconductor device 200.

FIG. 13 is a cross-sectional view illustrating an example of the wiring substrate 650.

FIG. 14 illustrates some processes of a manufacturing method of the semiconductor apparatus 600.

FIG. 15 is a diagram illustrating an example of via wiring 680 according to a reference example.

FIG. 16 is a diagram illustrating an example of a small-diameter via 731 provided in the wiring substrate 650.

### DESCRIPTION OF EXEMPLARY EMBODIMENTS

Hereinafter, the present invention will be described through embodiments of the invention, but the following embodiments do not limit the invention according to the claims. Further, not all of combinations of features described in the embodiments are essential to the solving means of the invention.

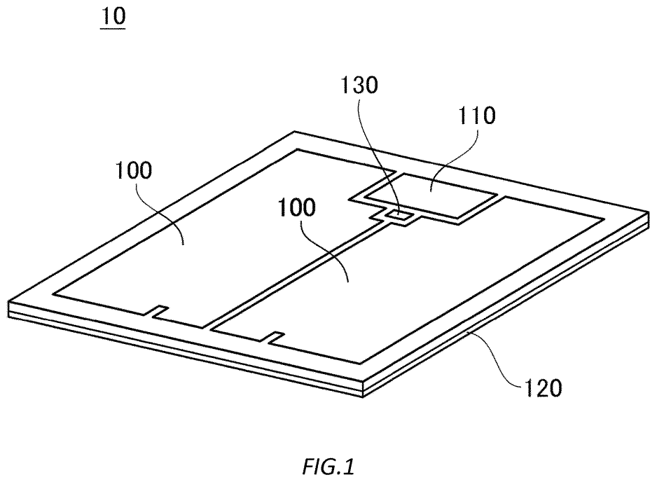

FIG. 1 is a perspective view of a switching element 10 according to the present embodiment. The switching element 10 is a semiconductor switching element such as a MOSFET or Metal-Oxide-Semiconductor Field-Effect Transistor. The switching element 10 may be a power MOSFET having a vertical structure. The switching element 10 may be a SiC semiconductor element such as a SiC-MOSFET capable of faster switching, or may be one in which a wide-gap semiconductor such as GaN, diamond, gallium nitride material, gallium oxide material, AlN, AlGaN, or ZnO is used. Instead of the above, the switching element 10 may be a semiconductor switching device such as an IGBT or Insulated Gate Bipolar Transistor or may be a SiC-IGBT.

The switching element 10 may be a semiconductor chip having a first main electrode 100 and a control electrode 110 on one surface, which is a surface on an upper side in the figure, and having a second main electrode 120 on an opposite surface. In the example of this figure, the switching element 10 further has a sense electrode 130 on the surface on the upper side in the figure. When the switching element 10 is a MOSFET, the switching element 10 has a source and a drain as the first main electrode 100 and the second main electrode 120, has a gate as the control electrode 110, and has a sense source as the sense electrode 130. When the switching element 10 is an IGBT, the switching element 10 has an emitter and a collector as the first main electrode 100 and the second main electrode 120, has a gate as the control electrode 110, and has a sense emitter as the sense electrode 130. In this embodiment, for convenience of description, the switching element 10 is illustrated as a MOSFET.

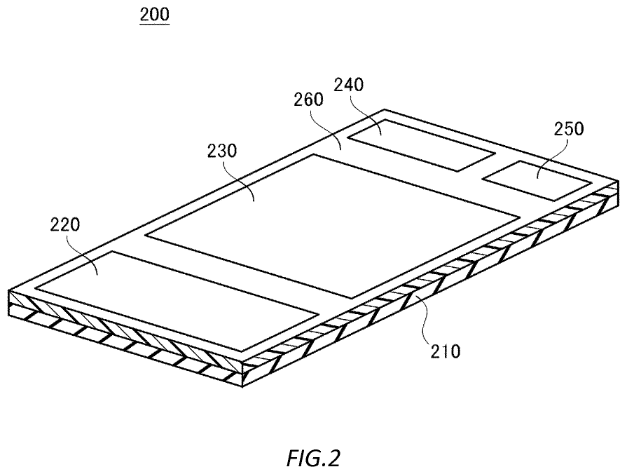

FIG. 2 is a perspective view of a semiconductor device 200 according to the present embodiment. In general, a semiconductor module using a switching element such as the switching element 10 illustrated in FIG. 1 has a structure in which one surface of the switching element, which is, for example, a surface on a side with the second main electrode 120, is bonded to a wiring pattern on a substrate and each electrode on another surface, which is, for example, each of the first main electrode 100, the control electrode 110, and the sense electrode 130, is electrically connected to another wiring pattern by wire bonding. Such a semiconductor module is implemented as an integral module by encapsulating, using a resin, a substrate on which the switching element is mounted, each bonding wire, and each metal plate connected to a positive terminal, a negative terminal and an output terminal.

In contrast, the semiconductor device 200 has a structure in which each electrode plate electrically connected to each electrode of the switching element 10 is exposed to one surface of the plate-shaped semiconductor device 200. In this embodiment, the semiconductor device 200 includes a mounting substrate 210, a first main electrode plate 220, a second main electrode plate 230, a control electrode plate 240, a sub-electrode plate 250, and an encapsulating portion 260.

The switching element 10 is mounted on a mounting surface, which is a surface on an upper side in the figure, of the mounting substrate 210. The first main electrode plate 220 is electrically connected to the first main electrode 100 of the switching element 10. The second main electrode plate 230 is electrically connected to the second main electrode 120 of the switching element 10. The control electrode plate 240 is electrically connected to the control electrode 110 of the switching element 10. The sub-electrode plate 250 is electrically connected to the first main electrode 100 of the switching element 10. Here, the first main electrode plate 220, the second main electrode plate 230, the control electrode plate 240, and the sub-electrode plate 250 are exposed to a surface opposite to a side with the mounting substrate 210 of the semiconductor device 200, the surface being on a side with the mounting surface for the switching element 10 in the mounting substrate 210. The encapsulating portion 260 covers the mounting surface for the switching element 10 in the mounting substrate 210 while exposing the first main electrode plate 220, the second main electrode plate 230, the control electrode plate 240, and the sub-electrode plate 250.

Instead of modularizing the switching element such as the switching element 10 as previously described, by bonding each electrode plate on one surface of the semiconductor device 200 to a wiring pattern on the substrate using the semiconductor device 200 of the present embodiment, all the electrodes necessary for the switching element 10 can be electrically connected to respective units of wiring on the substrate without wire bonding.

It should be noted that the semiconductor device 200 may further include an electrode that is electrically connected to the sense electrode 130, on the same surface as the first main electrode plate 220 or the like. While both of the first main electrode plate 220 and the sub-electrode plate 250 are electrically connected to the first main electrode 100 of the switching element 10, the first main electrode plate 220 has a larger area and is used for a large current to flow therethrough and the sub-electrode plate 250 is used for controlling the switching element 10 in a pair with the control electrode plate 240. In another form, the semiconductor device 200 may not include the sub-electrode plate 250. In this case, the first main electrode plate 220 is also used for controlling the switching element 10.

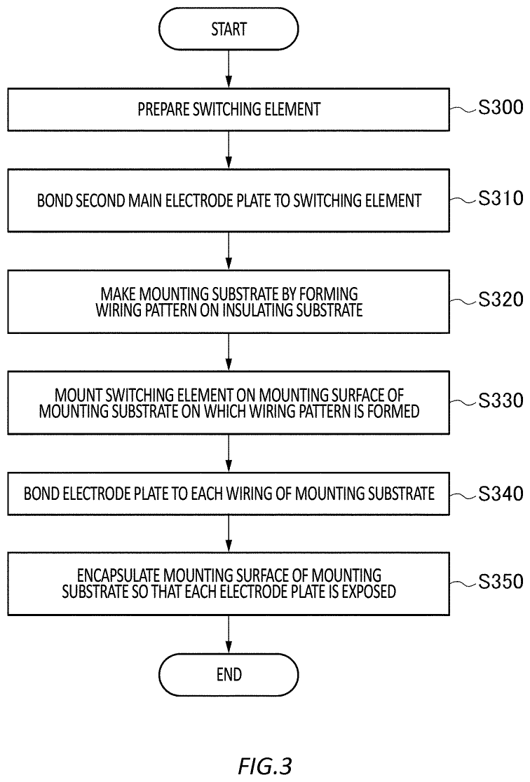

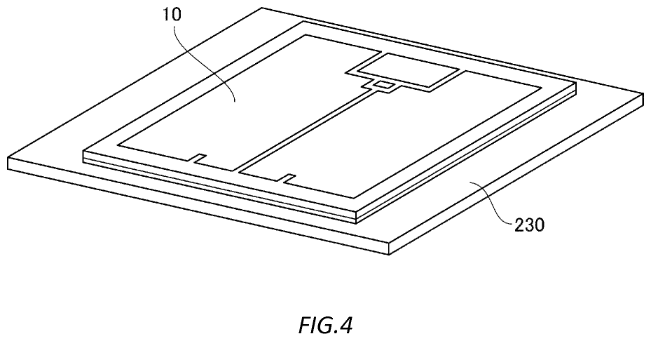

FIG. 3 illustrates a manufacturing method of the semiconductor device 200 according to the present embodiment. Hereinafter, the manufacturing method of the semiconductor device 200 will be described with reference to FIG. 4 to 7 illustrating a configuration in a middle of manufacture of the semiconductor device 200. In S300 or step 300, the switching element 10 is prepared, which has the first main electrode 100 and the control electrode 110 on one surface and has the second main electrode 120 on an opposite surface.

In S310, the second main electrode plate 230 is bonded to a surface on a side with the second main electrode 120 of the switching element 10. FIG. 4 is a perspective view of a configuration in which a second main electrode plate 230 is bonded to the switching element 10 according to the present embodiment. The second main electrode plate 230 is a conductive plate such as a copper plate. The second main electrode plate 230 may be bonded by using a nano-silver sintering agent or may be bonded by gold-to-gold direct bonding to the second main electrode 120. Thus, the second main electrode plate 230 is electrically connected to the second main electrode 120 of the switching element 10. As an alternative to the above, the second main electrode plate 230 may be bonded by a solder material or copper-to-copper direct bonding. A second main electrode of the switching element 10 may be bonded to a plurality of bumps arrayed regularly or irregularly on the second main electrode plate 230.

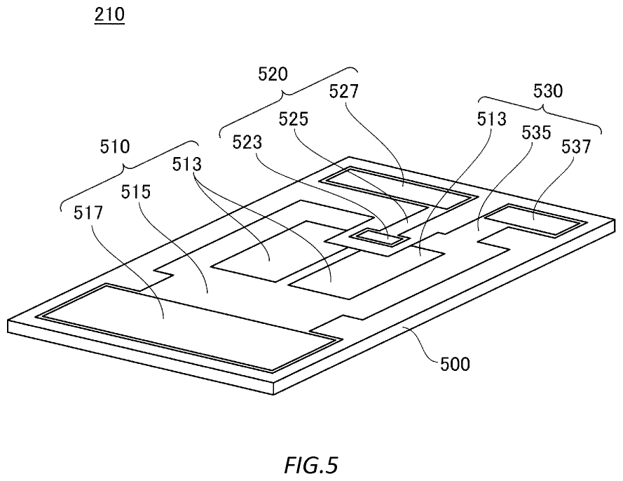

In S320, the mounting substrate 210 is made. FIG. 5 is a perspective view of the mounting substrate 210 according to the present embodiment. In this process, the mounting substrate 210 is made, which has a wiring pattern of first main electrode wiring 510, control wiring 520, and sub-wiring 530 on a mounting surface, to which the switching element 10 is intended to be mounted, in an insulating substrate 500 made of a material such as Si, silicon nitride, or aluminum nitride. For example, in addition to the above, the insulating substrate 500 may be made by using a ceramic material.

The first main electrode wiring 510 is formed from a conductive metal film or metal plate made of, for example, copper. The first main electrode wiring 510 includes a first main electrode contact 513, wiring 515, and a first main electrode plate contact 517. The first main electrode contact 513 is an area to which the first main electrode 100 of the switching element 10 is connected. The wiring 515 electrically connects the first main electrode contact 513 and the first main electrode plate contact 517. The first main electrode plate contact 517 is an area to which the first main electrode plate 220 is connected.

Similarly to the first main electrode wiring 510, the control wiring 520 is formed from a conductive metal film or metal plate made of, for example, copper. The control wiring 520 includes a control electrode contact 523, wiring 525, and a control electrode plate contact 527. The control electrode contact 523 is an area to which the control electrode 110 of the switching element 10 is connected. The wiring 525 electrically connects the control electrode contact 523 and the control electrode plate contact 527. The control electrode plate contact 527 is an area to which the control electrode plate 240 is connected.

Similarly to the first main electrode wiring 510, the sub-wiring 530 is formed from a conductive metal film or metal plate made of, for example, copper. The sub-wiring 530 includes a first main electrode contact 513, wiring 535, and a sub-electrode plate contact 537. The first main electrode contact 513 is shared with the first main electrode wiring 510. The sub-wiring 530 may utilize a part of the first main electrode contact 513 used by the first main electrode wiring 510. The wiring 535 electrically connects the first main electrode contact 513 and the sub-electrode plate contact 537. A wiring width of the wiring 535 may be smaller than that of the wiring 515. The sub-electrode plate contact 537 is an area to which the sub-electrode plate 250 is connected.

Here, a region bonded to each electrode of the switching element 10 such as the first main electrode contact 513 and the first main electrode plate contact 517 of the first main electrode wiring 510, the control electrode contact 523 and the control electrode plate contact 527 of the control wiring 520, and the sub-electrode plate contact 537 of the sub-wiring 530, or each electrode plate such as the first main electrode plate 220, the second main electrode plate 230, the control electrode plate 240 and the sub-electrode plate 250 may each have a plurality of bumps arrayed regularly or irregularly. The plurality of bumps may each be a conductive metal bump made of, for example, gold. The plurality of bumps may be formed by, for example, arranging a conductive metal bump precursor in each region by transfer and sintering the bump precursor to be cured.

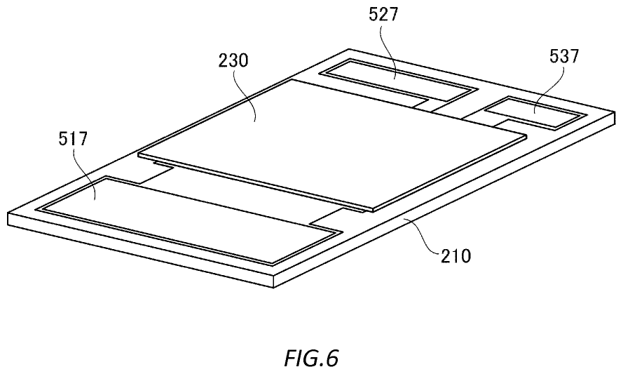

In S330, the switching element 10 is mounted on the mounting surface of the mounting substrate 210 on which each wiring pattern is formed. FIG. 6 is a perspective view of a configuration in which a switching element 10 to which the second main electrode plate 230 is bonded is bonded to the mounting substrate 210 according to the present embodiment. The switching element 10 to which the second main electrode plate 230 is bonded as illustrated in FIG. 4 is bonded to the mounting surface of the mounting substrate 210 so that a surface on an upper side of the switching element 10 in FIG. 4 is oriented downward. Thus, the first main electrode 100 of the switching element 10 is bonded to the first main electrode contact 513 of the first main electrode wiring 510 and the sub-wiring 530, and the control electrode 110 of the switching element 10 is bonded to the control electrode contact 523 of the control wiring 520. This bonding method may be similar to the bonding method used to bond the second main electrode plate 230 to the second main electrode 120.

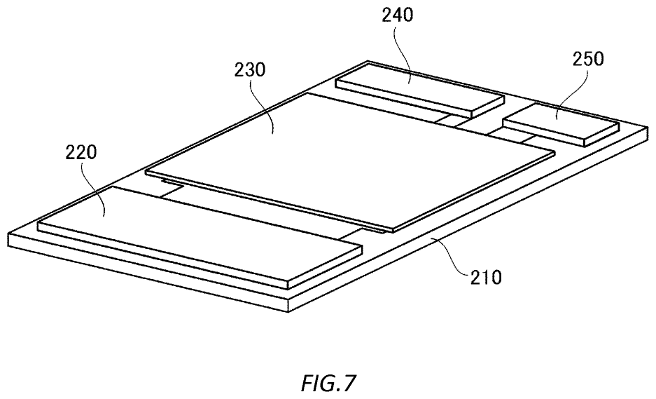

In S340, each electrode plate is bonded to each wiring of the mounting substrate 210. FIG. 7 is a perspective view of a configuration in which the first main electrode plate 220, the control electrode plate 240, and the sub-electrode plate 250 are bonded to the mounting substrate 210 according to the present embodiment. As illustrated in FIG. 6, the first main electrode plate contact 517 of the first main electrode wiring 510, the control electrode plate contact 527 of the control wiring 520, and the sub-electrode plate contact 537 of the sub-wiring 530 are positioned in a region, where the switching element 10 is not arranged, on the mounting surface of the mounting substrate 210 onto which the switching element 10 is intended to be mounted. In this process, the first main electrode plate 220, the control electrode plate 240, and the sub-electrode plate 250 are respectively bonded to the first main electrode plate contact 517, the control electrode plate contact 527, and the sub-electrode plate contact 537 as such. This bonding method may be similar to the bonding method used to bond the second main electrode plate 230 to the second main electrode 120.

Thus, the first main electrode plate 220, the control electrode plate 240, and the sub-electrode plate 250 are positioned in a region, where the switching element 10 is not arranged, on the mounting surface for the switching element 10, and are respectively electrically connected to the first main electrode wiring 510, the control wiring 520, and the sub-wiring 530. In this manner, the mounting substrate 210 is made, which has the insulating substrate 500 and the first main electrode wiring 510, the first main electrode plate 220, the control wiring 520, the control electrode plate 240, the sub-wiring 530 and the sub-electrode plate 250 that are formed on the insulating substrate 500.

Here, in the semiconductor device 200 according to the present embodiment, on the mounting surface for the switching element 10 in the mounting substrate 210, the switching element 10 is arranged between the first main electrode plate 220 and the control electrode plate 240. The sub-electrode plate 250 may be arranged on a same side as the control electrode plate 240 relative to the switching element 10. Thus, in the semiconductor device 200, control wiring can be connected to the control electrode plate 240 and the sub-electrode plate 250 positioned at one end of the semiconductor device 200.

In S350, the semiconductor device 200 illustrated in FIG. 2 is obtained by forming the encapsulating portion 260 by encapsulating the mounting surface of the mounting substrate 210 using the encapsulating material so that each electrode plate is exposed. Here, the encapsulating portion 260 covers the mounting surface for the switching element 10 in the mounting substrate 210 and a surface on a side with the mounting substrate 210 in the switching element 10 while exposing the first main electrode plate 220, the second main electrode plate 230, the control electrode plate 240, and the sub-electrode plate 250 to a terminal surface, which is a surface on an upper side in FIG. 2, of the semiconductor device 200. This encapsulation may be resin encapsulation using a molding material.

In this process, after encapsulating to cover the mounting surface for the switching element 10 in the mounting substrate 210 and the surface on the side with the mounting substrate 210 in the switching element 10, the terminal surface of the semiconductor device 200 may be ground to remove an excess amount of the encapsulating material so as to expose each electrode plate. In another embodiment, the encapsulation process may be omitted, and the semiconductor device 200 may not include the encapsulating portion 260. After this process, an anti-oxidation film may be formed, for example, by plating an exposed surface of each electrode plate with Sn.

According to the manufacturing method presented above, the semiconductor device 200 can be manufactured in which each terminal electrically connected to each electrode of the switching element 10 is exposed to one surface. Although the second main electrode plate 230 is bonded to a surface on a side with the second main electrode 120 of the switching element 10 in S310 in the manufacturing method presented above, this process may be omitted. In this case, the second main electrode 120 may be directly exposed to the terminal surface of the semiconductor device 200.

In the manufacturing method presented above, the order of each process may be changed if possible. For example, S340 may be performed before S330, so that the switching element 10 may be mounted on the mounting substrate 210 after each electrode plate is bonded to each wiring of the mounting substrate 210. S310 may be performed after S330, so that the second main electrode plate 230 is bonded to a surface on a side with the second main electrode 120 of the switching element 10 after the mounting substrate 210 is mounted on the switching element 10. Any of S300 or S310, or S320 may be performed prior to others, or S300 and S310, and S320 may be performed in parallel.

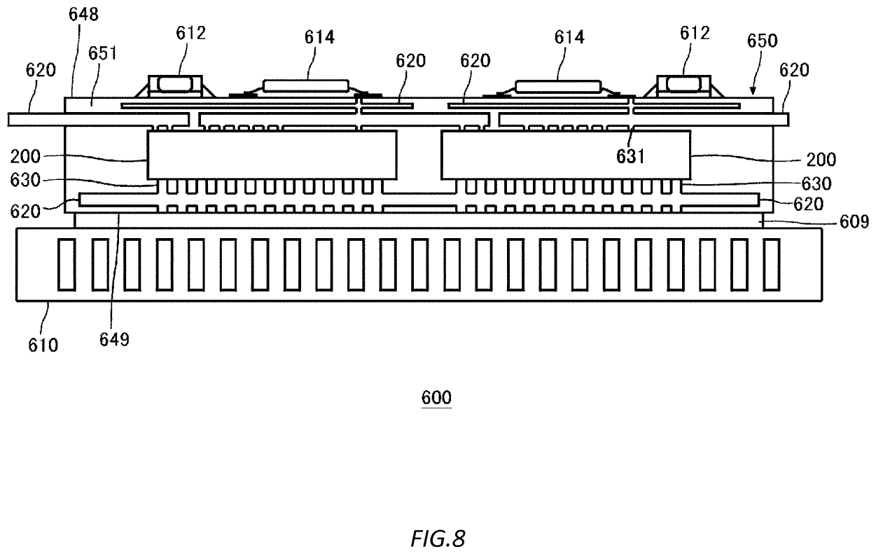

FIG. 8 is a cross-sectional view illustrating an example of the semiconductor apparatus 600 according to one embodiment of the present invention. The semiconductor apparatus 600 comprises a wiring substrate 650 and the semiconductor device 200. The wiring substrate 650 is a substrate in which circuit wiring is provided on an insulating core material. The semiconductor device 200 is embedded in the wiring substrate 650 and is connected to the circuit wiring. The semiconductor device 200 in this example is entirely embedded in the wiring substrate 650. The semiconductor device 200 may not be exposed from the wiring substrate 650, and a part of the semiconductor device 200 may be exposed.

The semiconductor device 200 may include a power transistor such as an IGBT or a MOSFET. The semiconductor device 200 may include the vertical switching element 10, in which the main current flows between the upper surface and the lower surface, as shown in FIG. 1, or may include a lateral switching element 10 in which the main current flows in a direction parallel to the upper surface. The switching element 10 is an example of the semiconductor chip.

As illustrated in FIG. 2, the semiconductor device 200 includes the switching element 10 and the mounting substrate 210. The mounting substrate 210 has a mounting surface arranged to face the first surface of the switching element 10.

The switching element 10 includes the first surface and the opposite second surface. The first surface in this example is the surface of the switching element 10 which is arranged to face the mounting surface of the mounting substrate 210. As illustrated in FIG. 1, the first main electrode 100 and the control electrode 110 are provided on the first surface of the switching element 10. Further, the second main electrode 120 is provided on the second surface of the switching element 10.

As shown in FIG. 7, the first main electrode plate 220 and the control electrode plate 240 are provided in a region on the mounting surface of the mounting substrate 210 that does not overlap with the switching element 10. The sub-electrode plate 250 is also provided in a region on the mounting surface of the mounting substrate 210 that does not overlap with the switching element 10.

As illustrated in FIG. 5, the mounting substrate 210 may be provided with the first main electrode wiring 510, the control wiring 520, and the sub-wiring 530. At least a part of the first main electrode wiring 510 is provided on the mounting surface of the mounting substrate 210, and connects the first main electrode 100 and the first main electrode plate 220. At least a part of the control wiring 520 is provided on the mounting surface of the mounting substrate 210, and connects the control electrode 110 and the control electrode plate 240. At least a part of the sub-wiring 530 is provided on the mounting surface of the mounting substrate 210, and connects the first main electrode 100 and the sub-electrode plate 250.

The semiconductor device 200 of this example is a package in which the two main electrode plates and the control electrode plate are exposed on the same surface. The semiconductor device 200 may include the vertical switching element 10 in which the two main electrodes are provided on different surfaces, as described in FIGS. 1 to 7. In another example, the semiconductor device 200 may include a semiconductor chip in which the two main electrodes and the control electrode are provided on the same surface. Even in this case, the semiconductor device 200 is a package in which the two main electrode plates and the control electrode plate are exposed on the same surface.

The wiring substrate 650 may have a core material formed of an insulating material. The core material may include a resin such as epoxy, and glass fiber. The circuit wiring is wiring formed of a conductive material on the core material. The circuit wiring may be, for example, a thin film of a metal such as copper. The wiring substrate 650 is, for example, a PCB substrate, but is not limited thereto. The wiring substrate 650 may be a multilayer wiring substrate in which a wiring layer and an insulating layer are stacked repeatedly a plurality of times.

In the example shown in this figure, the wiring substrate 650 has the upper surface 648, the lower surface 649, one or more units of in-plane wiring 620, one or more units of via wiring 631, and one or more units of via wiring 630. The upper surface 648 and the lower surface 649 are the two principal surfaces having the largest areas among the surfaces of the wiring substrate 650. The in-plane wiring 620, the via wiring 630, and the via wiring 631 are examples of the above-described circuit wiring. In this example, the in-plane wiring 620 is formed in a predetermined pattern in a plane parallel to the upper surface 648 of the wiring substrate 650. A plurality of layers of the in-plane wiring 620 may be provided at different height positions in the thickness direction of the wiring substrate 650.

The via wiring 630 and the via wiring 631 are provided so as to extend in the thickness direction of the wiring substrate 650. The via wiring 630 and the via wiring 631 electrically connect the two members provided at different height positions in the thickness direction of the wiring substrate 650. For example, the via wiring 630 and the via wiring 631 may connect the in-plane wiring 620 and the semiconductor device 200, and may also connect two units of the in-plane wiring 620.

In this figure, the via wiring on the upper surface 648 side of the semiconductor device 200 is referred to as the via wiring 631, and the via wiring on the lower surface 649 side is referred to as the via wiring 630. The via wiring 630 and the via wiring 631 may connect the member connected to the upper surface 648 or the lower surface 649 of the wiring substrate 650 and the member provided inside the wiring substrate 650.

An electric element 612 and an electric element 614 are provided on the upper surface 648 in this example. The electric element 612 and the electric element 614 may be passive elements such as a capacitor, a resistor, or a coil, may be active elements such as a transistor or a diode, or may be integrated circuits such as a semiconductor chip. The via wiring 631 may electrically connect the electric elements and the in-plane wiring 620 or the semiconductor device 200.

In this example, a cooling device 610 is connected to the lower surface 649. The cooling device 610 may have a flow path through which a refrigerant flows. The cooling device 610 may be fixed to the lower surface 649 via a connection layer 609. The connection layer 609 may include, for example, a metal plate such as copper, may include an adhesive member such as solder, and may also include grease. The via wiring 630 may electrically connect the connection layer 609 and the in-plane wiring 620 or the semiconductor device 200.

The wiring substrate 650 may have an encapsulating material 651. The encapsulating material 651 encapsulates the semiconductor device 200, the in-plane wiring 620, the via wiring 630, and the via wiring 631. The encapsulating material 651 is formed of an insulating material such as an epoxy resin. Although FIG. 8 illustrates one encapsulating material 651, the encapsulating material 651 may be divided into a plurality of layers in the thickness direction of the wiring substrate 650. The in-plane wiring 620 may be sandwiched between the encapsulating material 651 of the two layers. The encapsulating material 651 may be provided with the via wiring 630 or the via wiring 631.

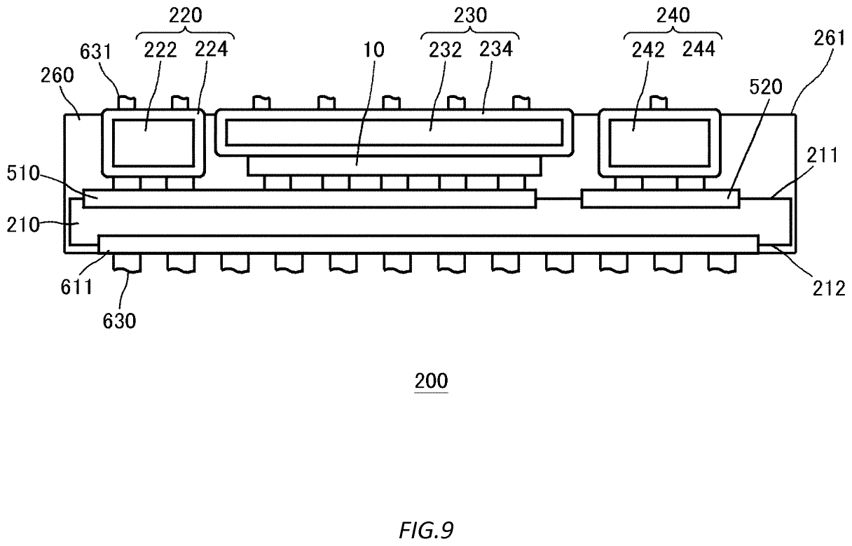

FIG. 9 is a cross-sectional view illustrating an example of the semiconductor device 200. The semiconductor device 200 may have a structure similar to the examples shown in FIGS. 2 to 7. The semiconductor device 200 in this example has an upper surface 261. The upper surface 261 is provided with the first main electrode plate 220, the second main electrode plate 230, and the control electrode plate 240 described in FIGS. 2 to 7.

The first main electrode plate 220 is connected to the first main electrode 100 (see FIG. 1) of the switching element 10 via the first main electrode wiring 510 provided on the mounting surface 211 of the mounting substrate 210. The first main electrode wiring 510 may be connected to the first main electrode plate 220 and the first main electrode 100 via the via wiring or the like.

The second main electrode plate 230 is connected to the second main electrode 120 (see FIG. 1) of the switching element 10. The second main electrode plate 230 may be connected to the second main electrode 120 via a conductive member such as solder.

The control electrode plate 240 is connected to the control electrode 110 (see FIG. 1) of the switching element 10 via the control wiring 520 provided on the mounting surface 211 of the mounting substrate 210. The control wiring 520 may be connected to the control electrode plate 240 and the control electrode 110 via the via wiring or the like.

On a surface 212 of the mounting substrate 210 of this example, which is opposite to the mounting surface 211, a conductive layer 611 is provided. The conductive layer 611 is, for example, a metal layer such as copper. The conductive layer 611 is connected to the in-plane wiring 620 and the like via the via wiring 630.

The via wiring 631 is connected to at least one of the first main electrode plate 220, the second main electrode plate 230, or the control electrode plate 240. In the example of this figure, the via wiring 631 is connected to all of the first main electrode plate 220, the second main electrode plate 230, and the control electrode plate 240. A plurality of units of the via wiring 631 may be connected to each of the electrode plates.

One or more units of the via wiring 631 provided on each of the electrode plates are in contact with the first main electrode plate 220, the second main electrode plate 230, or the control electrode plate 240. That the via wiring 631 is in contact with the electrode plate means that, at the interface between the via wiring 631 and the electrode plate, no material other than the material of the via wiring 631 and the material of the electrode plate is present. In the case where the surface of the core layer of each electrode plate is covered with a coating material such as plating, it means that, at the interface between the via wiring 631 and the electrode plate, no material other than the material of the via wiring 631, the material of the core layer, and the material of the coating material is present. By connecting the via wiring 631 and each electrode plate directly without interposing another material, it is possible to improve reliability of the electrical connection between the via wiring 631 and each electrode plate.

The first main electrode plate 220 of this example has a core layer 222 and a plating layer 224. The plating layer 224 covers a part or all of the surface of the core layer 222. The core layer 222 is, for example, copper, and the plating layer 224 is gold. However, the material of each member is not limited to this.

The second main electrode plate 230 of this example has a core layer 232 and a plating layer 234. The plating layer 234 covers a part or all of the surface of the core layer 232. The core layer 232 is, for example, copper, and the plating layer 234 is gold. However, the material of each member is not limited to this.

The control electrode plate 240 of this example has a core layer 242 and a plating layer 244. The plating layer 244 covers a part or all of the surface of the core layer 242. The core layer 242 is, for example, copper, and the plating layer 244 is gold. However, the material of each member is not limited to this.

The material of the plating layer of each of the electrode plates may be the same as the material of the via wiring 631. In this case, the material of the core layer of the electrode plates may be different from the material of the via wiring 631. In the case where each of the electrode plates does not have a plating layer, the material of the core layer may be the same as the material of the via wiring 631.

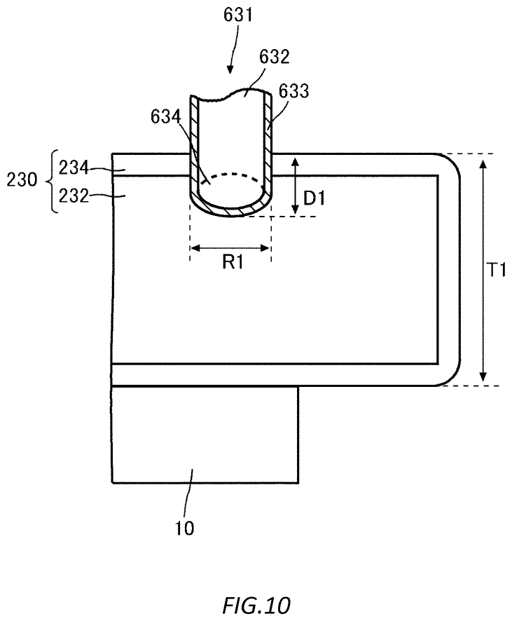

FIG. 10 is a diagram illustrating an example of an enlarged view of the via wiring 631. In this example, the via wiring 631 provided in the second main electrode plate 230 is illustrated; however, the via wiring 631 provided in the first main electrode plate 220 and the via wiring 631 provided in the control electrode plate 240 may also have a similar structure. In the description of FIG. 10, the “second main electrode plate 230″ may be read as the ”first main electrode plate 220″ or the “control electrode plate 240.”

The via wiring 631 of this example includes a hole 632 and a wiring portion 633. The hole 632 is a cavity formed in the wiring substrate 650. The wiring portion 633 is a conductive member formed on the inner wall of the cavity. The wiring portion 633 may be formed so that a cavity remains inside the hole 632, or may fill the entire hole 632.

The via wiring 631 may be formed to extend into the inside of the second main electrode plate 230. Similarly, the via wiring 631 of the first main electrode plate 220 and the control electrode plate 240 may also be formed to extend into the inside of the first main electrode plate 220 or the control electrode plate 240. Accordingly, it is possible to further improve reliability of the connection between the via wiring 631 and each electrode plate.

Each via wiring 631 is connected to each electrode plate. Each electrode plate may have a larger thickness than each electrode provided in the switching element 10. For example, the thickness T1 of the first main electrode plate 220, the second main electrode plate 230, and the control electrode plate 240 may each be 100 μm or more. Each electrode plate may be, for example, a metal block such as copper. By using a metal block, each electrode plate can be more easily made thicker than each electrode of the switching element 10 formed on the surface of the semiconductor substrate. By increasing the thickness of each electrode plate, it becomes easier to form the via wiring 631 to extend into the inside of each electrode plate. The thickness of each electrode plate may be 250 μm or more, may be 300 μm or more, or may be 500 μm or more. The thickness T1 of each electrode plate may be 1000 μm or less, or may be 800 μm or less.

In this example, the via wiring 631 may be provided so as to extend 20 μm or more inside the first main electrode plate 220, the second main electrode plate 230, or the control electrode plate 240. In the example of FIG. 10, the length D1 from the upper surface of the second main electrode plate 230 to the lower end of the via wiring 631 is 20 μm or more. The length D1 of this example is the length in the direction perpendicular to the upper surface of the second main electrode plate 230. By ensuring the length D1 of 20 μm or more, it is possible to further improve reliability of the connection between the via wiring 631 and each electrode plate. The length D1 may be 30 μm or more, may be 35 μm or more, or may be 40 μm or more. The length D1 may be 100 μm or less, may be 75 μm or less, or may be 50 μm or less.

The length D1 may be larger than the thickness of the plating layer 234. That is, the via wiring 631 may be provided so as to penetrate through the plated layer 234. In this case, the via wiring 631 is in contact with both the plating layer 234 and the core layer 232. At the interface between the via wiring 631 and the plating layer 234, materials other than the material of the via wiring 631 and the material of the plating layer 234 may not be present. At the interface between the via wiring 631 and the core layer 232, materials other than the material of the via wiring 631 and the material of the plating layer 234 may not be present.

The via wiring 631 in this example may be formed by a mechanical drill. In this case, after forming the hole 632 with a mechanical drill, the wiring portion 633 is formed. The mechanical drill is a rod-shaped member whose edge is tapered. A groove or a convex portion in a helical shape or in another shape may be formed on a side surface of the mechanical drill. The hole 632 is formed by rotating the mechanical drill.

Since the via wiring 631 is connected to each relatively thick electrode plate, it is possible to form the hole 632 by using a mechanical drill. By forming the via wiring 631 with a mechanical drill, the hole 632 can be easily formed to extend into the inside of each electrode plate. Therefore, it is possible to improve reliability of the connection between the via wiring 631 and each electrode plate.

In the case where the via wiring 631 is formed by using a mechanical drill, the indentation 634 formed by contact with the edge of the mechanical drill may be formed near the bottom surface of the hole 632. The indentation 634 may be a surface having less unevenness than other side surfaces of the hole 632. On the side surfaces other than the indentation 634 of the hole 632, for example, a helical groove or a convex portion may be formed. Further, the wiring portion 633 may also have unevenness similar to the surface of the hole 632. That is, the surface of the wiring portion 633 in the vicinity of the bottom of the via wiring 631 may have less unevenness than the surface of the wiring portion 633 on the side surface on the upper side of the portion.

The diameter R1 of the via wiring 631 may be 200 μm or more. The diameter R1 is the width of the via wiring 631 in a direction parallel to the surface of each electrode plate. The diameter R1 may be determined using the maximum width of the via wiring 631 on the surface of each electrode plate. For example, in the case where the cross section of the via wiring 631 is circular, the diameter R1 is the diameter of the cross section of the via wiring 631.

By increasing the diameter R1 of the via wiring 631, it is possible to improve reliability of the connection between the via wiring 631 and each electrode plate. By forming the via wiring 631 using a mechanical drill, it is possible to easily form the via wiring 631 having the large diameter R1. The diameter R1 may be 300 μm or more, or may be 400 μm or more. The diameter R1 may be 1000 μm or less, may be 800 μm or less, or may be 500 μm or less.

The interface of the first main electrode plate 220, the second main electrode plate 230, or the control electrode plate 240 with respect to the via wiring 631 may be in contact with the via wiring 631 without melting. In the case where the hole 632 is formed by a mechanical drill, the interface of each electrode plate is in contact with the via wiring 631 in a non-melted state. On the other hand, when the hole 632 is formed by the laser, the interface of each electrode plate is in a melted state.

In this figure, the via wiring 631 was mainly formed by using a mechanical drill. As a result, it is possible to form the via wiring 631 at a low cost and with high reliability. On the other hand, the hole 632 of the via wiring 631 may be formed by a laser or the like. Even in this case, the via wiring 631 and each electrode plate are directly connected. For example, after embedding the semiconductor device 200 in the wiring substrate 650, the via wiring 631 directly connected to each electrode plate can be formed by forming the hole 632 with a laser or the like.

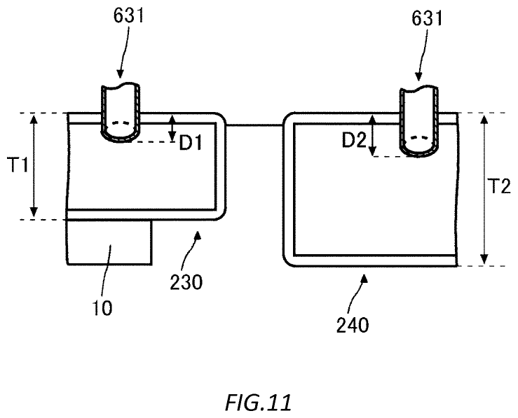

FIG. 11 is a diagram illustrating an example of the via wiring 631 provided in each electrode plate. The via wiring 631 of each electrode plate may be embedded in each electrode plate by the same length D1 (see FIG. 10). In the example of this figure, the length by which the via wiring 631 extends inside each of the first main electrode plate 220, the second main electrode plate 230, and the control electrode plate 240 may be different according to the thickness of each of the electrode plates. For example, the larger the thickness of the electrode plate, the larger the length by which the via wiring extends inside the electrode plate may be.

In the example of this figure, the thickness T1 of the second main electrode plate 230 is smaller than the thickness T2 of the control electrode plate 240. In this case, the length D1 by which the via wiring 631 extends inside the second main electrode plate 230 may be smaller than the length D2 by which the via wiring 631 extends inside the control electrode plate 240. With such a structure, it is possible to further improve connection reliability between the thick electrode plate and the via wiring 631. As illustrated in FIG. 7, the switching element 10 is arranged below the second main electrode plate 230. The second main electrode plate 230 may be thinner than either of the first main electrode plate 220 or the control electrode plate 240. The thicknesses of the first main electrode plate 220 and the control electrode plate 240 may be the same.

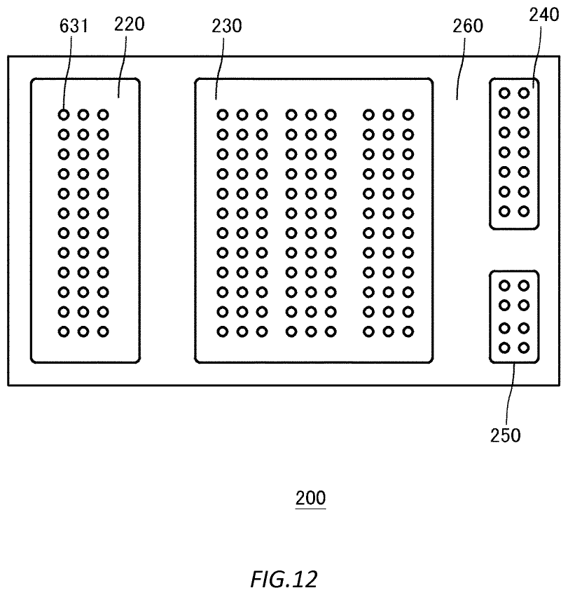

FIG. 12 is a diagram illustrating an arrangement example of each electrode plate on the upper surface of the semiconductor device 200. The upper surface of each electrode plate is exposed from the encapsulating portion 260, and one or more units of the via wiring 631 are connected to the upper surface of each electrode plate. In FIG. 12, the via wiring 631 is indicated by a circle.

In the semiconductor device 200 of this example, the area of the upper surface of at least one of the electrode plates is larger than the area of the corresponding electrode in the switching element 10. For example, the area of the control electrode plate 240 is larger than the area of the control electrode 110. The area of the control electrode plate 240 may be twice, or more, or may be four times, or more, as large as the area of the control electrode 110. Therefore, a larger number of units of the via wiring 631 can be connected to the control electrode plate 240 than in the case where the via wiring 631 is connected to the control electrode 110. Accordingly, it is possible to improve connection reliability between each circuit wiring of the wiring substrate 650 and the control electrode 110.

The area of the second main electrode plate 230 may also be larger than the area of the second main electrode 120. The area of the first main electrode plate 220 may also be larger than the area of the first main electrode 100. This makes it possible to improve connection reliability between each electrode plate and each circuit wiring.

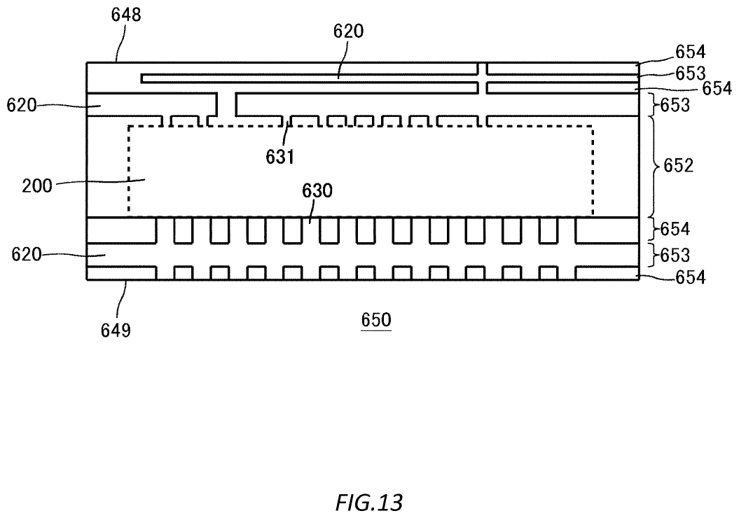

FIG. 13 is a cross-sectional view illustrating an example of the wiring substrate 650. In this figure, a region in which the semiconductor device 200 is embedded is indicated by the broken line. The structure of the circuit wiring inside the wiring substrate 650 is similar to the example shown in FIG. 8.

The wiring substrate of this example includes a core material 652, and one or more insulating layers 654 and one or more wiring layers 653 stacked on the core material 652. The core material 652 is formed of an insulating material. For example, the core material 652 may include a resin such as epoxy, and glass fiber. The core material 652 may be formed by impregnating a glass cloth, woven with glass fibers, with resin. The insulating layer 654 may be formed by bonding a resin sheet to the core material 652 or the wiring layer 653 and then applying heat and pressure. The via wiring 631 is formed in the insulating layer 654. The wiring layer 653 may be formed by stacking a metal foil such as copper on the core material 652 or the insulating layer 654. The in-plane wiring 620 can be formed by patterning the wiring layer 653 into the predetermined shape.

The wiring layer 653 or the insulating layer 654 may be stacked on the core material 652. The insulating layer 654 is formed on the wiring layer 653, and the wiring layer 653 is formed on the insulating layer 654.

The semiconductor device 200 of this example is entirely embedded in the core material 652. The upper surface or the lower surface of the semiconductor device 200 may be arranged at the same height position as the upper surface or the lower surface of the core material 652.

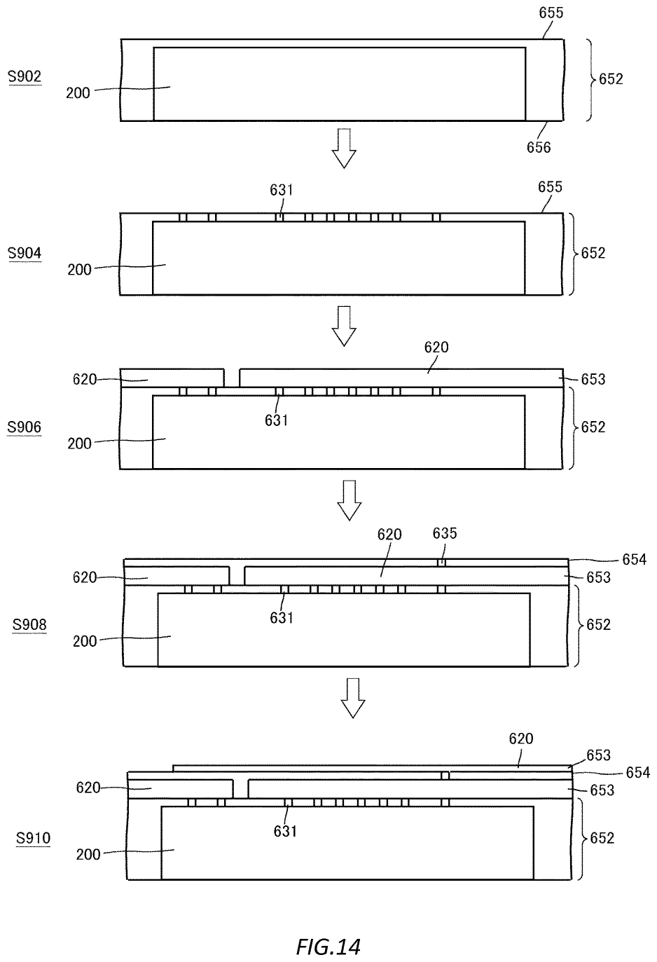

FIG. 14 shows some processes of the manufacturing method of the semiconductor apparatus 600. In the embedding step S902, the semiconductor device 200 is embedded in the member for forming the wiring substrate 650. In the example of this figure, the semiconductor device 200 is embedded in the core material 652 in a state where the insulating layer 654 and the wiring layer 653 are not stacked. In the embedding step S902, the core material 652 is heated so that the core material 652 becomes softened, and, in this softened state, the semiconductor device 200 is pressed against, and inserted into, the lower surface 656 of the core material 652. In the embedding step S902, the semiconductor device 200 is exposed on the lower surface 656 of the core material 652, and is not exposed on the upper surface 655.

Next, in the via forming step S904, one or more units of the via wiring 631, which are in contact with the control electrode plate 240, the first main electrode plate 220, or the second main electrode plate 230, are formed in the member in which the semiconductor device 200 is embedded. In S904, the via wiring 631 may be formed for all of the control electrode plate 240, the first main electrode plate 220, and the second main electrode plate 230. In the example of this figure, the via wiring 631 is formed in the core material 652 between the upper surface 655 and the semiconductor device 200.

As described above, the via wiring 631 may be formed by a mechanical drill. In the example of this figure, the hole 632 (see FIG. 10) may be formed in the core material 652 by a mechanical drill. By forming the wiring portion 633 (see FIG. 10) in the hole 632, the via wiring 631 can be formed. The wiring portion 633 may also be formed on at least a part of the upper surface 655 of the core material 652.

In the first wiring layer stacking step S906, the wiring layer 653 is stacked on the core material 652. In the example of this figure, the semiconductor device 200 is embedded in the core material 652, and, after the via wiring 631 is formed in the core material 652, the wiring layer 653 is stacked on the upper surface 655 of the core material 652. In S906, the wiring layer 653 is electrically connected to the via wiring 631. By patterning the wiring layer 653, the in-plane wiring 620 can be formed.

In the insulating layer stacking step S908, the insulating layer 654 is stacked on the wiring layer 653. The via wiring 635 connected with the in-plane wiring 620 may be formed in the insulating layer 654.

In the second wiring layer stacking step S910, the wiring layer 653 is stacked on the insulating layer 654. In S910, the wiring layer 653 is electrically connected to the via wiring 635. By patterning the wiring layer 653, the in-plane wiring 620 can be formed.

Thus, by alternately stacking the wiring layer 653 and the insulating layer 654 on the upper surface 655 side of the core material 652, the structure on the upper surface 648 side of the wiring substrate 650 can be formed. In FIG. 14, the processes up to S910 are illustrated, but a larger number of the wiring layers 653 and the insulating layers 654 may be stacked on the upper surface 655 side of the core material 652. Similarly, also for the lower surface 656 of the core material 652, the structure on the lower surface 649 side of the wiring substrate 650 can be formed by alternately stacking the insulating layer 654 and the wiring layer 653. Accordingly, the semiconductor apparatus 600 can be manufactured.

According to this example, after embedding the semiconductor device 200 in the core material 652 and the like, the via wiring 631 that reaches each electrode plate is formed. Therefore, it is possible to bring the via wiring 631 into contact with each electrode plate to be directly connected to each other. Accordingly, it is possible to improve reliability of the connection between the via wiring 631 and each electrode plate.

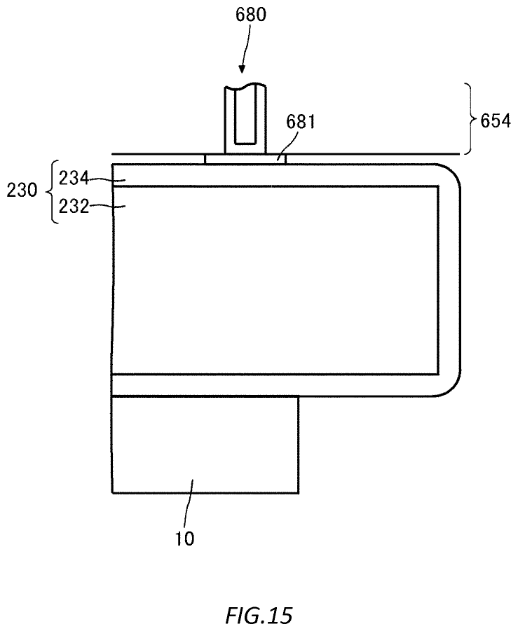

FIG. 15 is a diagram illustrating an example of the via wiring 680 according to the reference example. In this example, the via wiring 680 is formed before the semiconductor device 200 is embedded in the wiring substrate 650. More specifically, after forming a cavity for inserting the semiconductor device 200 into the wiring substrate 650 and forming the via wiring 680 so as to be exposed on the surface of the cavity, the semiconductor device 200 is inserted into the cavity. In this case, a connection portion 681 for connecting the via wiring 680 and the electrode plate is formed on the surface of the cavity.

In the reference example, since the connection portion 681 is provided between the via wiring 680 and the electrode plate, the via wiring 680 and the electrode plate are not directly connected. In this example, two interfaces are present, which are the interface between the via wiring 680 and the connection portion 681, and the interface between the connection portion 681 and the electrode plate. For this reason, reliability of the connection between the via wiring 680 and the electrode plate is decreased.

In each embodiment described in this specification, the via wiring 631 and each electrode plate are in contact with each other and are directly connected, so that it is possible to improve reliability of connection between the via wiring 631 and each electrode plate. In the reference example, the material surrounding the via wiring 680 is not in contact with the upper surface of each electrode plate. For example, in the case of FIG. 15, although the periphery of the via wiring 680 is surrounded by the insulating layer 654, the insulating layer 654 is not in contact with the upper surface of the electrode plate.

In contrast, the member surrounding the via wiring 631 according to the embodiment may be in contact with each electrode plate. For example, in the example illustrated in FIG. 14, the core material 652 surrounding the via wiring 631 is in contact with the upper surface of each electrode plate.

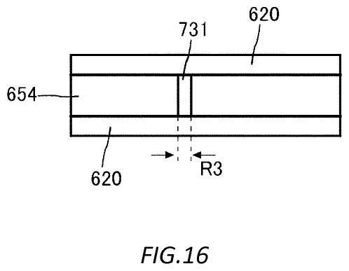

FIG. 16 is a diagram illustrating an example of a small-diameter via 731 provided in the wiring substrate 650. The diameter R3 of the small-diameter via 731 is smaller than the diameter of the via wiring 631. The diameter R3 of the small-diameter via 731 may be equal to or less than half, or may be equal to or less than one-fourth, of the diameter of the via wiring 631. The small-diameter via 731 is in contact with the conductive layer such as the in-plane wiring 620 provided in the wiring substrate 650 or the electrode of the semiconductor device 200.

The small-diameter via 731 may be provided in a path through which a smaller current than the via wiring 631 flows. For example, in the path connected to the control electrode plate 240, the small-diameter via 731 may be provided instead of the via wiring 631. In the path that is connected to the first main electrode plate 220 or the second main electrode plate 230, the via wiring 631 may be provided.

The small-diameter via 731 may be formed by a laser. As a result, it is possible to easily form the fine small-diameter via 731. Further, at least a part of the interface between the small-diameter via 731 and the conductive layer may be melted. The small-diameter via 731 does not have to extend into inside of the conductive layer. Alternatively, the length by which the small-diameter via 731 extends inside the conductive layer may be smaller than the length by which the via wiring 631 extends inside the electrode plate.

In each embodiment described in this specification, in the wiring substrate 650, a passive element may be embedded and an active element may also be embedded in addition to the semiconductor device 200. In addition to the semiconductor device 200, an integrated circuit may be embedded in the wiring substrate 650. The integrated circuit may generate a control signal to be input to the control electrode plate 240.

While the embodiments of the present invention have been described, the technical scope of the present invention is not limited to the above-described embodiments. It is apparent to persons skilled in the art that various alterations or improvements can be added to the above-described embodiments. It is also apparent from the claims that the embodiments added with such alterations or improvements can be included in the technical scope of the present invention.

The operations, procedures, steps, and stages or the like of each process performed by an apparatus, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, and drawings, it does not necessarily mean that the process must be performed in this order.

What is claimed is:

1. A semiconductor apparatus comprising:
a wiring substrate on which circuit wiring is provided; and
a semiconductor device embedded in the wiring substrate and connected to the circuit wiring,
wherein the semiconductor device has an upper surface, and a first main electrode plate and a control electrode plate provided on the upper surface, and
wherein the wiring substrate has one or more units of via wiring in contact with the control electrode plate or the first main electrode plate.

2. The semiconductor apparatus according to claim 1, wherein the semiconductor device includes:
a semiconductor chip including a first surface and a second surface on an opposite side; and
a mounting substrate having a mounting surface arranged to face the first surface of the semiconductor chip,
wherein the semiconductor chip includes a first main electrode and a control electrode provided on the first surface, and a second main electrode provided on the second surface,
wherein the first main electrode plate and the control electrode plate are provided in a region of the mounting surface that does not overlap with the semiconductor chip,
wherein the mounting substrate includes
first main electrode wiring which is provided on the mounting surface and which connects the first main electrode and the first main electrode plate, and
control electrode wiring which is provided on the mounting surface and which connects the control electrode and the control electrode plate.

3. The semiconductor apparatus according to claim 1, wherein the wiring substrate includes
a core material, and
one or more insulating layers and one or more wiring layers stacked on the core material,
wherein the semiconductor device is embedded in the core material.

4. The semiconductor apparatus according to claim 2, wherein the wiring substrate includes
a core material, and
one or more insulating layers and one or more wiring layers stacked on the core material,
wherein the semiconductor device is embedded in the core material.

5. The semiconductor apparatus according to claim 1, wherein thicknesses of the first main electrode plate and the control electrode plate are both 100 μm or more.

6. The semiconductor apparatus according to claim 2, wherein thicknesses of the first main electrode plate and the control electrode plate are both 100 μm or more.

7. The semiconductor apparatus according to claim 5, wherein the via wiring extends 20 μm or more inside the control electrode plate or the first main electrode plate.

8. The semiconductor apparatus according to claim 6, wherein the via wiring extends 20 μm or more inside the control electrode plate or the first main electrode plate.

9. The semiconductor apparatus according to claim 5, wherein a diameter of the via wiring is 200 μm or more.

10. The semiconductor apparatus according to claim 6, wherein a diameter of the via wiring is 200 μm or more.

11. The semiconductor apparatus according to claim 2, wherein an area of the control electrode plate is larger than an area of the control electrode.

12. The semiconductor apparatus according to claim 1, wherein an interface between the via wiring and the control electrode plate or the first main electrode plate is in contact with the via wiring without melting.

13. The semiconductor apparatus according to claim 2, wherein an interface between the via wiring and the control electrode plate or the first main electrode plate is in contact with the via wiring without melting.

14. The semiconductor apparatus according to claim 12, comprising one or more small-diameter vias having a diameter smaller than the via wiring and being in contact with a conductive layer,
wherein an interface of the conductive layer in contact with the small-diameter vias is melted.

15. The semiconductor apparatus according to claim 13, comprising one or more small-diameter vias having a diameter smaller than the via wiring and being in contact with a conductive layer,
wherein an interface of the conductive layer in contact with the small-diameter vias is melted.

16. The semiconductor apparatus according to claim 2,
wherein the semiconductor device further includes a second main electrode plate connected to the second main electrode,
wherein the via wiring is provided for each of the first main electrode plate, the second main electrode plate, and the control electrode plate, and
the via wiring has a different length extending inside each electrode plate in accordance with respective thicknesses of the first main electrode plate, the second main electrode plate, and the control electrode plate.

17. A manufacturing method of a semiconductor apparatus in which a semiconductor device is embedded in a wiring substrate, the semiconductor device including an upper surface and a first main electrode plate and a control electrode plate provided on the upper surface,
the manufacturing method comprising:
embedding the semiconductor device in a member forming the wiring substrate; and
forming, in the member in which the semiconductor device is embedded, one or more units of via wiring in contact with the control electrode plate or the first main electrode plate.

18. The manufacturing method according to claim 17, wherein the via wiring is formed by a mechanical drill.

19. The manufacturing method according to claim 17, wherein the wiring substrate includes:
a core material, and
one or more insulating layers and one or more wiring layers stacked on the core material,
wherein, after the semiconductor device is embedded in the core material, the insulating layer and the wiring layer are stacked on the core material.

20. The manufacturing method according to claim 18, wherein the wiring substrate includes:
a core material, and
one or more insulating layers and one or more wiring layers stacked on the core material,
wherein, after the semiconductor device is embedded in the core material, the insulating layer and the wiring layer are stacked on the core material.
